(19) United States
(12) Patent Application Publication
(10) Pub. No.: US 2024/0361704 A1
(43) Pub. Date: Oct. 31, 2024

(54) METHOD FOR SIMULATING ILLUMINATION AND IMAGING PROPERTIES OF AN OPTICAL PRODUCTION SYSTEM DURING THE ILLUMINATION AND IMAGING OF AN OBJECT BY MEANS OF AN OPTICAL MEASUREMENT SYSTEM

(71) Applicant: Carl Zeiss SMT GmbH, Oberkochen (DE)

(72) Inventors: Klaus Gwosch, Aalen (DE); Markus Koch, Neu-Ulm (DE); Renzo Capelli, Heidenheim (DE); Matthias Roesch, Aalen (DE); Lars Stoppe, Jena (DE); Manuel Decker, Jena (DE)

(21) Appl. No.: 18/768,476

(22) Filed: Jul. 10, 2024

Related U.S. Application Data
(63) Continuation of application No. PCT/EP2023/050450, filed on Jan. 10, 2023.

(30) Foreign Application Priority Data
Jan. 14, 2022 (DE) 102022200372.1

(51) Int. Cl. G03F 7/00

(52) U.S. Cl. CPC G03F 7/70666; G03F 7/70625; G03F 7/70641; G03F 7/706849

(57) ABSTRACT

When simulating illumination and imaging properties of an optical production system when illuminating and imaging an object by use of an optical measurement system of a metrology system, the optical measurement system having an illumination optical unit for illuminating the object and a pupil stop, in particular a displaceable pupil stop, and having an imaging optical unit for imaging the object into an image plane is initially provided. When simulating the properties of the optical production system with the optical measurement system, a plurality of pupil stops are initially provided. Measurement aerial images are then recorded by use of the plurality of pupil stops. A complex mask transfer function is reconstructed from the recorded measurement aerial images and a 3-D aerial image is determined from this function and the illumination setting of the optical production system. This yields an improved simulation method.

### CROSS-REFERENCE TO RELATED APPLICATIONS

The present patent application is a continuation of and claims benefit under 35 U.S.C. § 120 from PCT Application No. PCT/EP2023/050450, filed on Jan. 10, 2023, which claims priority to German patent application DE 10 2022 200 372.1, filed on Jan. 14, 2022. The entire contents of each of these earlier applications are incorporated by reference herein.

### TECHNICAL FIELD

The invention relates to a method for simulating illumination and imaging properties of an optical production system during the illumination and imaging of an object by use of an optical measurement system. Further, the invention relates to a metrology system for carrying out such a method.

### BACKGROUND

Such a method and a metrology system to this end are known from DE 10 2019 208 552 A1 and DE 10 2019 215 800 A1. A metrology system for measuring an aerial image of a lithography mask in three dimensions is known from WO 2016/012426 A1. DE 10 2013 219 524 A1 describes a device and a method for determining an imaging quality of an optical system, and an optical system. DE 10 2013 219 524 A1 has described a phase retrieval method for determining a wavefront on the basis of the imaging of a pinhole. The specialist article “A new system for a wafer level CD metrology on photomasks,” proceedings of SPIE—The International Society for Optical Engineering, 2009, 7272, by Martin et al. has disclosed a metrology system for determining a wafer level critical dimension (CD).

### SUMMARY

It is an aspect of the present invention to improve a method for simulating illumination and imaging properties of an optical production system when illuminating and imaging an object by use of an optical measurement system.

This aspect is achieved according to the invention by a simulation method having the features specified in claim 1.

According to the invention, it was recognized that the recording of measurement aerial images by use of the plurality of pupil stops, in particular the recording of measurement aerial images in a plurality of measurement positions of a pupil stop, which was selected in advance for the best possible simulation of the illumination setting of the optical production system, provides the possibility of improving the accuracy of the simulation method overall and in particular provides the option of reducing illumination angle-dependent artefacts, in particular, in the reconstructed complex mask transfer function, that is to say in the transfer function of the imaged object. It is then possible to correctly take account of 3-D mask effects. This can be taken into account when examining lithography masks, especially when examining masks used for EUV lithography.

Within the scope of the simulation method, it is possible to select precisely one pupil stop from the plurality of pupil stops provided, which may differ in terms of their stop boundary shape and/or in terms of their stop boundary orientation. Alternatively, it is possible to select and use a plurality of different pupil stops for the purpose of specifying different measurement positions. The pupil stops provided may specify at least one of the following illumination settings in particular: Quadrupole, C-quad, dipole, annular, conventional. A person skilled in the art finds examples for such settings in, inter alia, WO 2012/028303 A1. First of all, there may be an initial determination of a best focal plane (defocus value zₘ=0) within the preparation of the imaging method. z-increments when determining the 3-D aerial image in the last step of the simulation method, i.e. when determining the aerial image from the reconstructed mask transfer function and the optical production system illumination setting, may differ from defocus values that may at first be specified in the simulation method. Pixel sizes of the recorded measurement aerial images may be sampled for the purpose of an adaptation to the desired pixel resolution.

The target pupil stop, which can be specified, and the target stop boundary shape thereof may relate to a plurality of, or else a multiplicity of, individual illumination or pupil spots, i.e. a plurality of stop apertures for example arranged in a grid-like manner. Such illumination or pupil spots may yield an illumination setting used within the scope of the production illumination, the said illumination setting for example being able to be set by way of an illumination optical unit having a field facet mirror and a pupil facet mirror.

A displacement drive as claimed in claim 2 has proven its worth for the reproducible specification of pupil stop measurement positions. This correspondingly applies to the object holder that is displaceable perpendicular to the object plane.

Different stop boundary shapes and/or stop boundary orientations of the provided pupil stops as claimed in claim 3 increase a flexibility when carrying out the simulation method.

A simulation method as claimed in claim 4 with the aid of a qualification algorithm has particularly proven its worth. The defocus values and/or the pupil stop measurement positions can be specified with the aid of an object holder that is displaceable by actuator, and with the aid of a displacement drive for pupil stop displacement. A piezo drive and/or a stepper motor drive can be used as displacement drive or displacement actuator.

Recording the measurement aerial images as claimed in claim 5 has proven its worth in practice.

A central measurement position and a plurality of offset measurement positions as claimed in claim 6 have proven their worth within the scope of the practical implementation of the simulation method. In the central measurement position, the pupil stop is arranged in the center of the utilized pupil of the optical measurement system. Provision can be made of two to ten offset measurement positions, in particular two to five, for example three or four offset measurement positions. The offset measurement positions can be arranged uniformly distributed in the circumferential direction about the central measurement position. The offset measurement positions may be displaced relative to the central measurement position in the Cartesian directions or else in the directions of the quadrants. The measurement positions may be arranged randomly in the circumferential direction and may be arranged on one or more radii, in particular on two or three different radii. A completely random arrangement of the measurement positions within the measurement pupil or else partially outside of the measurement pupil is also possible. Should a random arrangement be mentioned above, the latter can be determined by the use of an algorithmic random function.

Defocus value/measurement position combinations as claimed in claim 7 have proven their worth in practice. It was found that it is not necessary to home in on all pupil stop measurement positions, specified within the scope of the method, for each defocus value. This reduces the measurement time.

A selection method for the pupil stop as claimed in claim 8 ensures the best possible simulation of the target pupil stop using the selected pupil stop. In the respective pupil spots, illumination light is present in the illumination pupil. A distance qualification of assigned pupil spots of the target stop boundary shape of the respective pupil stop can be carried out within the scope of the selection method. A merit function can be defined and minimized within the scope of the selection method.

Modeling the illumination direction-dependent mask spectrum as claimed in claim 9 has proven its worth during the reconstruction as this helps reduce the number of degrees of freedom present during the optimization within the scope of the reconstruction.

Displacing the imaging pupil stop as claimed in claim 10 extends the modelling possibilities within the scope of the simulation method.

A reconstruction as claimed in claim 11 leads to a particularly good simulation.

The result of the simulation method as claimed in claim 12 lies in the option of an aerial image description also dependent on a chief ray angle of an illumination by the optical production system. Therefore, a different illumination chief ray angle of the production system may also be taken into account when determining the 3-D aerial image. This increases the power of the simulation method.

The advantages of the metrology system as claimed in claims 13 to 15 correspond to those that have already been explained above with reference to the method claims.

A selection apparatus having a stop storage unit as claimed in claim 16 advantageously enables the pupil stop selection step of the simulation method. In particular, the selection can be made with the aid of a robotic actuation system which takes the respective selected pupil stop from the stop storage unit and moves it to its use location in the pupil plane. The selection apparatus moreover ensures a substitution of a last-used pupil stop for a newly selected pupil stop. In particular, the last-used pupil stop can be transferred from the use location back to the stop storage unit by use of the robotic actuation system in that case.

An aperture of the stop, i.e. of the illumination pupil stop and/or the imaging pupil stop, may also be variably specifiable, for example in the style of an iris diaphragm.

The metrology system may comprise a light source for the illumination light. A light source of this type may be configured as an EUV light source.

An EUV wavelength of the light source may range between 5 nm and 30 nm. A light source in the DUV wavelength range, for example of the order of 193 nm, is also possible.

### BRIEF DESCRIPTION OF DRAWINGS

Exemplary embodiments of the invention are explained in greater detail below with reference to the drawing, in which:

FIG. 1 very schematically shows a side view of a metrology system for simulating illumination and imaging properties of an optical production system when illuminating and imaging an object, the metrology system comprising an illumination optical unit and an imaging optical unit, both of which are depicted very schematically in each case;

FIGS. 2A to 9D show different variants of a metrology system pupil stop which is arrangeable in the region of an illumination pupil of the illumination optical unit;

FIG. 10 shows an example of an illumination setting of the optical production system to be simulated, represented by an intensity distribution over an illumination pupil in an optical production system pupil plane;

FIGS. 11A to 11I show an embodiment of a sequence of measurement positions of one of the pupil stops according to FIGS. 2 to 9 using the example of the pupil stop according to FIG. 2B, with the measurement position sequence being used within a method, performed by the metrology system, for simulating the illumination and imaging properties of the optical production system when illuminating and imaging the object using the metrology system optical measurement system;

FIGS. 12A to 12F show a further embodiment of a sequence of measurement positions of the metrology system pupil stop in a representation similar to that of FIGS. 11A to 11I;

FIGS. 13A to 13I show a further embodiment of a sequence of measurement positions of the metrology system pupil stop in a representation similar to that of FIGS. 11A to 11I;

FIGS. 14A to 14C show a further embodiment of a sequence of measurement positions of the metrology system pupil stop in a representation similar to that of FIGS. 11A to 11I;

FIG. 15 shows, in a pupil coordinate representation, a comparison between a target illumination setting of the production system, which is intended to be approximated by a metrology system pupil stop, and a pupil stop candidate using the example of a metrology system pupil stop comparable to the pupil stop according to FIG. 7A, with this comparison being part of an algorithm for selecting at least one metrology system pupil stop from the provided plurality of pupil stops;

FIG. 16 shows a plan view of a binary, periodic test structure which is arranged at XVI in the metrology system according to FIG. 1;

FIG. 17 shows, likewise in a plan view according to FIG. 16, a field distribution of an electromagnetic field of the illumination light in the illumination light beam path at XVII in FIG. 1, following an irradiation of the test structure;

FIG. 18 shows, once again in a plan view according to FIG. 16, a diffraction spectrum of the test structure in the illumination light beam path at XVIII in FIG. 1;

FIG. 19 shows, in a representation similar to FIG. 18, the diffraction spectrum that has been curtailed at the edge on account of an aperture stop of the metrology system, said aperture stop being at XIX in FIG. 1;

FIG. 20 shows, in a representation similar to FIG. 19, the diffraction spectrum including wavefront influences, indicated as height contours, by the metrology system imaging optical unit as measured spectrum in the region of an exit pupil of the imaging optical unit at XX in FIG. 1;

FIG. 21 shows, in a plan view similar to FIG. 17, a complex field distribution of the illumination light upon irradiation of a spatially resolving detection device of the metrology system in the imaging light beam path at XXI in FIG. 1; and

FIG. 22 shows, in a representation similar to FIG. 21, an illumination light intensity, as measured by the detection device, at the location of the detection device at XXII in FIG. 1.

### DETAILED DESCRIPTION

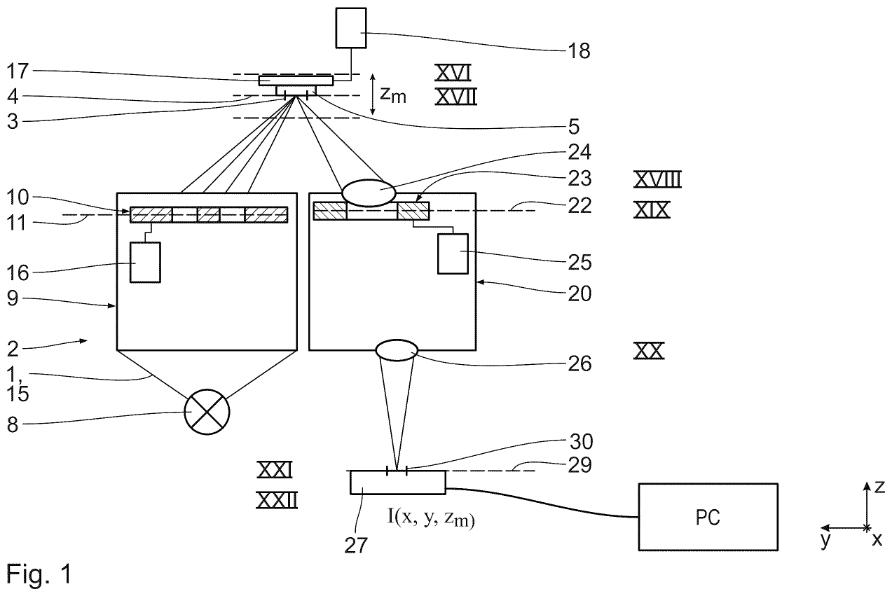

In order to facilitate the representation of positional relationships, a Cartesian xyz-coordinate system will be used hereinafter. In FIG. 1, the x-axis extends perpendicularly to the plane of the drawing into the latter. The y-axis extends to the left in FIG. 1. The z-axis extends vertically upwards in FIG. 1.

In a view that corresponds to a meridional section, FIG. 1 shows a beam path of EUV illumination light or imaging light 1 in a metrology system 2 for simulation of illumination and imaging properties of an optical production system when an object is illuminated and imaged by use of an optical measurement system of the metrology system 2. In this case, a test structure 5 arranged in an object field 3 in an object plane 4 is imaged.

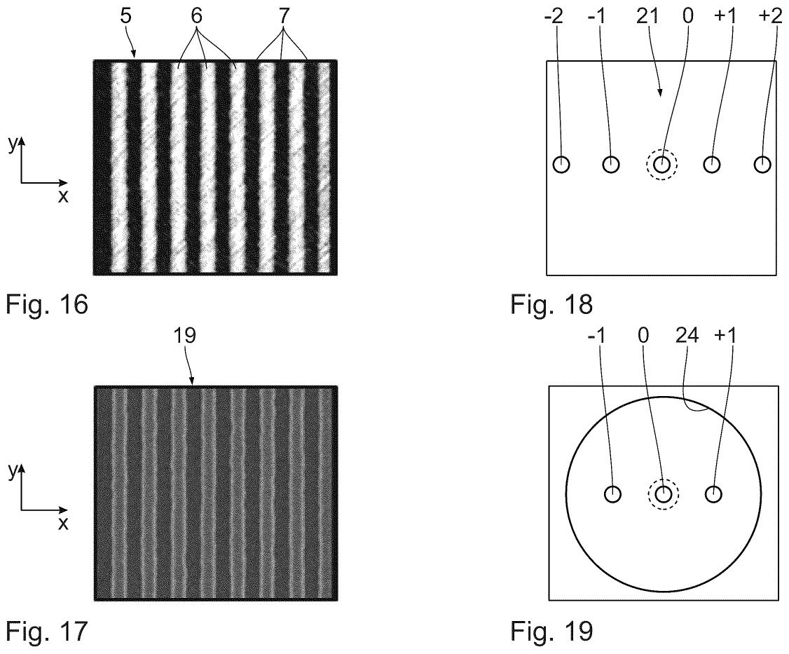

An example of the test structure 5 is depicted in a plan view in FIG. 16. The test structure 5 is periodic in one dimension, specifically along the y-coordinate for example. The test structure 5 is embodied as a binary test structure with absorber lines 6 and in each case alternating multilayer lines 7 which reflect the illumination light 1. The lines 6, 7 are vertical structures, which extend e.g. along the y-direction.

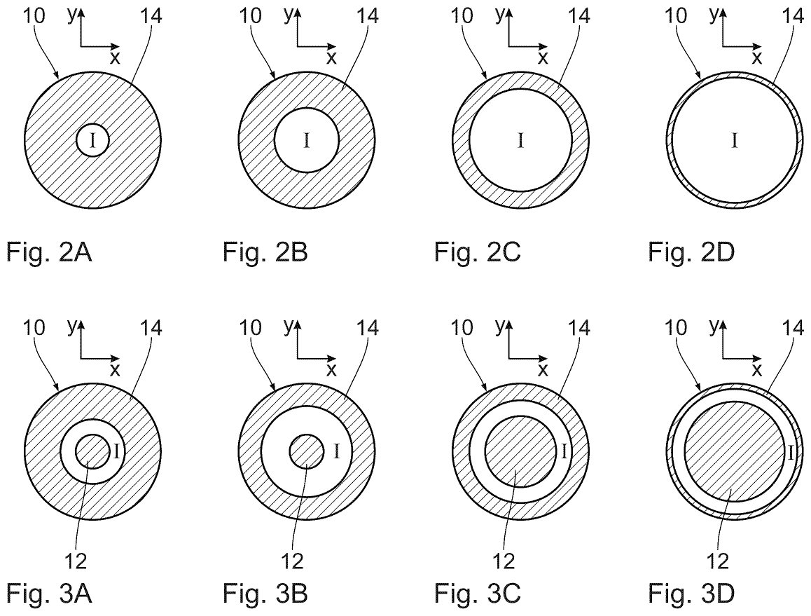

The metrology system 2 is used to analyze a three-dimensional (3-D) aerial image (aerial image metrology system). One application is found in the simulation of an aerial image of a lithography mask, in the way that the aerial image would also appear in an optical production system of a producing projection exposure apparatus, for example in a scanner. To this end, an imaging quality of the metrology system 2 itself, in particular, can be measured and optionally adjusted. Consequently, the analysis of the aerial image can serve to determine the imaging quality of a projection optical unit of the metrology system 2, or else to determine the imaging quality of, in particular, projection optical units within a projection exposure apparatus. Metrology systems are known from WO 2016/012426 A1, from US 2013/0063716 A1 (cf. FIG. 3 therein), from DE 102 20 815 A1 (cf. FIG. 9 therein), from DE 102 20 816 A1 (cf. FIG. 2 therein) and from US 2013/0083321 A1.

The illumination light 1 is reflected and diffracted at the test structure 5. A plane of incidence of the illumination light 1 is parallel to the yz-plane in the case of the central, initial illumination.

The EUV illumination light 1 is produced by an EUV light source 8. The light source 8 can be a laser plasma source (LPP; laser produced plasma) or a discharge source (DPP; discharge produced plasma). In principle, a synchrotron-based light source can also be used, e.g. a free electron laser (FEL). A used wavelength of the EUV light source can range between 5 nm and 30 nm. In principle, in one variant of the metrology system 2, a light source for another used light wavelength can also be used instead of the light source 8, for example a light source for a used wavelength of 193 nm.

An illumination optical unit 9 of the metrology system 2 is arranged between the light source 8 and the test structure 5. The illumination optical unit 9 serves for the illumination of the test structure 5 to be examined, with a defined illumination intensity distribution over the object field 3 and at the same time with a defined illumination angle distribution with which the field points of the object field 3 are illuminated. Such an illumination angle distribution is also referred to as illumination setting.

The respective illumination angle distribution of the illumination light 1 is specified by way of a pupil stop 10, which is arranged in an illumination optical unit pupil plane 11. The pupil stop 10 is also referred to as a sigma stop.

FIGS. 2A to 9B show possible embodiments of such pupil stops 10, which can be used as alternatives in the illumination optical unit 9 of the metrology system 2 for the purpose of specifying the illumination setting. Components and functions corresponding to those already explained in relation to a preceding figure are not discussed again in detail in a subsequent figure, and, where applicable, are denoted there using the same reference signs.

FIG. 2A shows a pupil stop 10 with a single central passage pole I. A radius of this passage pole I is approximately a quarter of a diameter of a peripheral aperture stop portion 14 of the pupil stop 10. A central illumination angle for the object field 3 with relatively small angular variation is selected by way of the pupil stop 10 according to FIG. 2A.

Further variants of pupil stops 10 with a central passage pole I of increasingly larger radius are shown in FIGS. 2B to 2D. There is an according increase in object field illumination angle variation when the pupil stops 10 according to FIGS. 2B to 2D are used. The pupil stop 10 according to FIG. 2D yields a conventional illumination setting, in which light can pass through the illumination optical unit pupil plane 11 of the metrology system 2 practically unimpeded.

FIG. 3A shows a variant of a pupil stop 10 with a ring-shaped passage portion I, which is arranged around a round, central obscuration stop portion 12. An internal diameter of the ring-shaped passage pole I for the pupil stop according to FIG. 3A is approximately the same size as an external diameter of the illumination pole I of the pupil stop 10 according to FIG. 2A. An external diameter of the ring-shaped passage pole I of the pupil stop 10 according to FIG. 3A is approximately twice the size.

FIG. 3B shows a variant of the pupil stop 10 in which, in comparison with FIG. 2A, an external diameter of the ring-shaped passage pole I is approximately 2.5-times as large as the internal diameter. The central obscuration stop portion 10 for the pupil stop 10 according to FIG. 3B is the same size as the one according to FIG. 3A.

FIG. 3C shows a variant of the pupil stop 10 with a ring-shaped passage pole I with an internal diameter approximately doubled in size in comparison with that of FIGS. 3A and 3B, and with an external diameter that is only slightly larger than that of the passage pole I according to FIG. 3B. This results in a correspondingly large central obscuration stop portion 12.

FIG. 3D shows an illumination pupil 10 with a ring-shaped illumination pole I, the ring-shaped thickness of which approximately corresponds to that of the embodiment according to FIG. 3C, with a diameter of the ring-shaped illumination pole I being maximized in the embodiment according to FIG. 3D, and so only a relatively thin aperture stop portion 14 remains on the side of the edge. This results in a correspondingly large central obscuration stop portion 12, which is larger in the embodiment according to FIG. 3D than in the embodiment according to FIG. 3C.

Corresponding annular illumination settings can be realized using the embodiments of the pupil stops 10 according to FIGS. 3A to 3D.

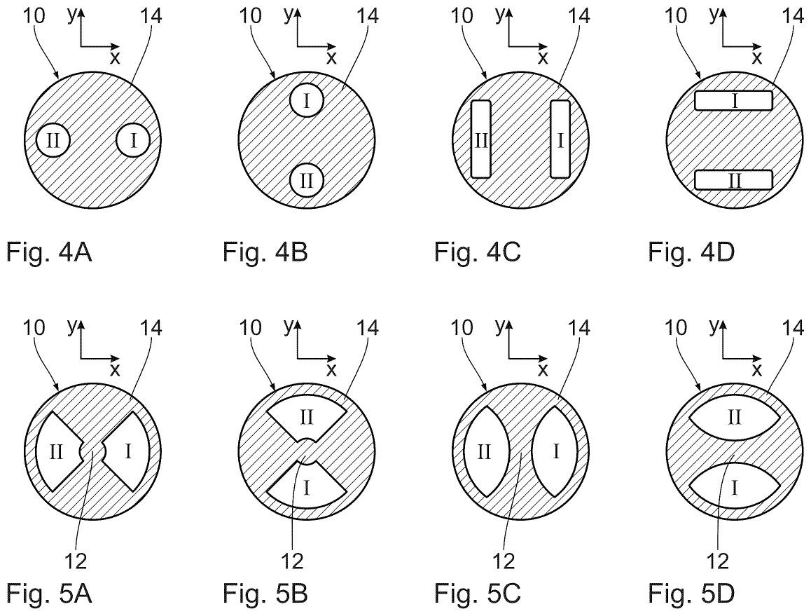

FIG. 4A shows a dipole pupil stop 10 embodied as an x-dipole. The two poles I and II are round in each case and have a diameter which in each case corresponds to the diameter of the central passage pole I of the pupil stop 10 according to FIG. 2A.

FIG. 4B shows a dipole pupil stop 10 embodied as a y-dipole with poles I, II which correspond to those of the embodiment according to FIG. 4A in terms of their shape and size. The pupil stop 10 according to FIG. 4B can be produced by rotating the pupil stop 10 according to FIG. 4A through 90° about an axis parallel to the z-axis.

FIG. 4C shows a further embodiment of an x-dipole pupil stop 10 with passage poles I, II which have a rectangular embodiment with an x/y-aspect ratio of approximately 1/4.

FIG. 4D shows a y-dipole pupil stop 10 corresponding to the x-dipole pupil stop 10 according to FIG. 4C.

FIG. 5A in turn shows an x-dipole pupil stop 10, with each of the open poles I, II having a circumferential extent of approximately 90°. Once again, a central obscuration stop portion 12 is located between the two passage poles I, II.

FIG. 5B in turn shows a y-dipole pupil stop 10 corresponding to the x-dipole pupil stop 10 according to FIG. 5A.

FIG. 5C shows an x-dipole pupil stop 10, in which the individual poles I, II are embodied as leaflets, i.e. each have a biconvex shape.

FIG. 5D shows a y-dipole pupil stop 10 corresponding to the x-dipole pupil stop 10 according to FIG. 5C.

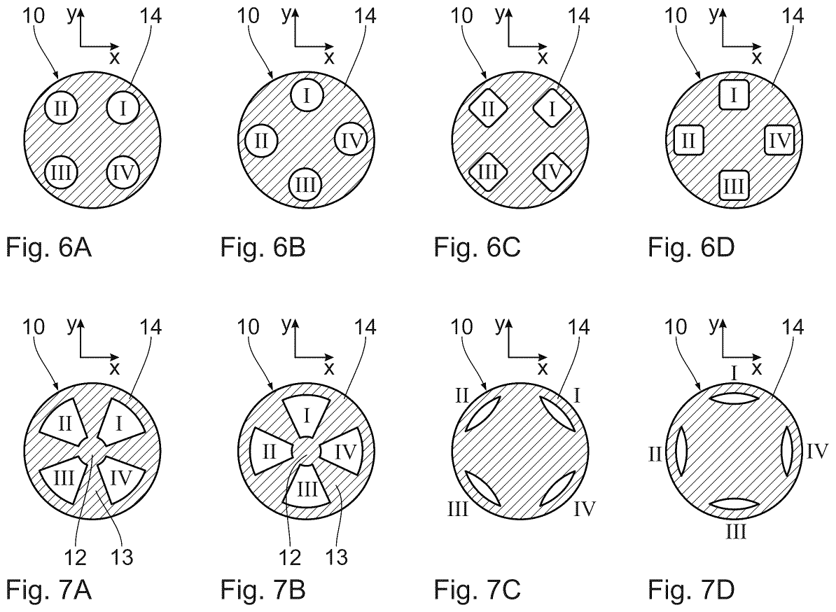

FIG. 6A shows an embodiment of a quadrupole pupil stop 10 with four round passage poles I, II, III and IV arranged in the quadrants. A diameter of these passage poles I to IV corresponds to that of the passage pole I of the pupil stop 10 according to FIG. 2A.

FIG. 6B shows a variant of the pupil stop 10 which can be produced from the variant according to FIG. 6A by way of a twist through 45° about an axis parallel to the z-axis, in which variant the four poles I to IV are thus arranged as a superposition of an x-dipole pupil stop and a y-dipole pupil stop according to FIGS. 4A and 4B.

FIG. 6C shows a variant of a corresponding quadrupole pupil stop 10 with square passage poles I to IV, once again arranged in the quadrants.

FIG. 6D in turn shows the arrangement corresponding to FIG. 6B, albeit with square passage poles I to IV, rotated through 45° in comparison with FIG. 6C.

FIG. 7A shows a variant of a quadrupole pupil stop 10 with sector-type poles I to IV arranged in the quadrants, each having a circumferential extent of approximately 45°. Connecting pieces 13 between adjacent passage poles I to IV of the pupil stop 10 according to FIG. 7A likewise have a circumferential extent of approximately 45° in each case. Once again, a central obscuration stop portion 12 is located in the center of the pupil stop 10 according to FIG. 7A.

FIG. 7B shows a quadrupole pupil stop 10 which corresponds to the embodiment according to FIG. 7A and which can be produced by rotation through 45° about an axis parallel to the z-axis.

FIG. 7C shows a variant of a quadrupole pupil stop 10 with passage poles I to IV in the form of leaflets which, in the circumferential direction around a stop center, are arranged in the vicinity of the aperture stop portion 14 on the side of the edge.

FIG. 7D shows a variant of the quadrupole pupil stop which corresponds to that according to FIG. 7C and which can be produced by rotation through 45° about an axis parallel to the z-axis.

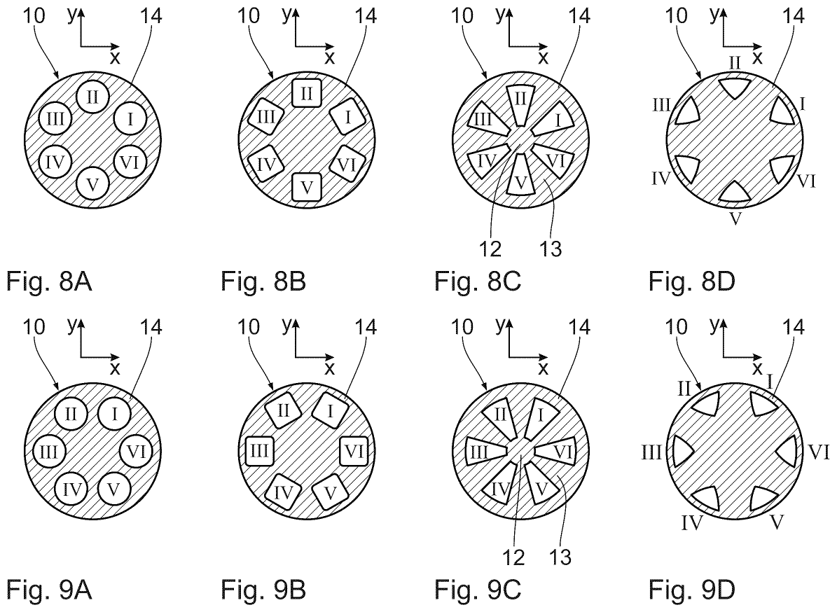

FIG. 8A shows a hexapole pupil stop 10 with six round passage poles I to VI which are arranged about the stop center so as to be uniformly distributed in the circumferential direction. A diameter of the poles I to VI corresponds to that of the passage pole I of the pupil stop 10 according to FIG. 2A. A distance between two adjacent poles I to VI is approximately one third of a pole diameter.

Measured from the x-coordinate of the pupil stop 10 of FIG. 8A, the six poles are arranged at the positions of 30°, 90°, 150°, 210°, 270° and 330°.

FIG. 8B shows a variant of a hexapole pupil stop 10 which corresponds to that according to FIG. 8A, apart from the edge contour of the passage poles I to VI which is square in the embodiment according to FIG. 8B.

FIG. 8C shows a variant of a hexapole pupil stop 10 which corresponds to that according to FIG. 8A, apart from the edge contour of the passage poles I to VI which is sector-type in the embodiment according to FIG. 8C. A circumferential extent of the sector-type passage poles I to VI is approximately 30° and corresponds to a circumferential extent of the connecting pieces between in each case adjacent passage poles I to VI.

FIG. 8D shows a variant of a hexapole pupil stop 10 which corresponds to that according to FIG. 8A, apart from the edge contour of the passage poles I to VI which is approximately triangular near the aperture stop portion 14 on the side of the edge in the embodiment according to FIG. 8D.

FIG. 9A shows a variant of a hexapole pupil stop 10 which can be produced from the variant according to FIG. 8A by way of a rotation through 30° about an axis parallel to the z-axis.

FIG. 9B shows a variant of a hexapole pupil stop 10 which can be produced from the variant according to FIG. 8B by way of a rotation through 30° about an axis parallel to the z-axis.

FIG. 9C shows a variant of a hexapole pupil stop 10 which can be produced from the variant according to FIG. 8C by way of a rotation through 30° about an axis parallel to the z-axis.

FIG. 9D shows a variant of a hexapole pupil stop 10 which can be produced from the variant according to FIG. 8D by way of a rotation through 30° about an axis parallel to the z-axis.

The pupil stop 10 of the illumination optical unit 9 is embodied as a stop which is displaceable in driven fashion and which is arranged in front of the object plane 4 in an illumination light beam path 15 of the illumination light 1. A drive unit used for the driven displacement of the pupil stop 10 is depicted at 16 in FIG. 1. By use of the drive unit 16, also referred to as a displacement drive, the pupil stop can be displaced along the x-coordinate and/or along the y-coordinate. A fine setting along the z-coordinate for the purpose of adjusting a match of an arrangement plane of the pupil stop 10 relative to the illumination optical unit pupil plane 11 is also possible by way of the drive unit 16. Moreover, the drive unit 16 can be designed such that a tilt of the stop about at least one tilt axis parallel to the x-axis and/or parallel to the y-axis is possible. Additionally, a diameter of the obscuration stop portion 12 and/or aperture stop portion 14 and/or a size of the poles I; I, II; I, II, III, IV; I, II, III, IV, V, VI of the respective embodiment of the pupil stop 10 may be specifiable in settable and, in particular, driven fashion.

With the aid of the displacement drive 16, it is possible to displace the selected pupil stop 10 along the pupil coordinates kₓ and k_{y} in the pupil plane 11.

The displacement drive 16 may also include a stop interchange unit, by means of which a specific pupil stop 10 is replaced with another, specific pupil stop 10. To this end, the stop interchange unit may take the respective selected pupil stop from a stop storage unit and return the replaced stop to this stop storage unit.

The test structure 5 is held by an object holder 17 of the metrology system 2. The object holder 17 cooperates with an object displacement drive 18 for displacing the test structure 5, in particular along the z-coordinate.

Following reflection at the test structure 5, the electromagnetic field of the illumination light 1 has a distribution 19 which is depicted in FIG. 18 in a plan view corresponding to that of FIG. 17. In the field distribution 19, amplitudes and phase values correspond to the absorber lines 6 and the multilayer lines 7 of the test structure 5.

The illumination light 1 reflected by the test structure 5 enters an imaging optical unit or projection optical unit 20 of the metrology system 2.

A diffraction spectrum 21 arises in a pupil plane of the projection optical unit 20 on account of the periodicity of the test structure 5 (cf. FIG. 18).

In the diffraction spectrum 21, the 0th order of diffraction of the test structure 5 is present centrally. In addition, FIG. 18 also represents the +/−1st order of diffraction and the +/−2nd order of diffraction of the diffraction spectrum 21.

The orders of diffraction of the diffraction spectrum 21 depicted in FIG. 18 appear in this form in a pupil plane of the optical system of the metrology system 2, for example in an entrance pupil plane 22 of the projection optical unit 20. An aperture stop 23 of the projection optical unit 20, which delimits an entrance pupil 24 of the projection optical unit 20 on the side of the edge, is arranged in this entrance pupil plane 22. The aperture stop 23 is also referred to as the imaging pupil stop of metrology system 2.

The imaging pupil stop 23 is operatively connected to a displacement drive 25, the function of which corresponds to that of the displacement drive 16 for the sigma stop 10.

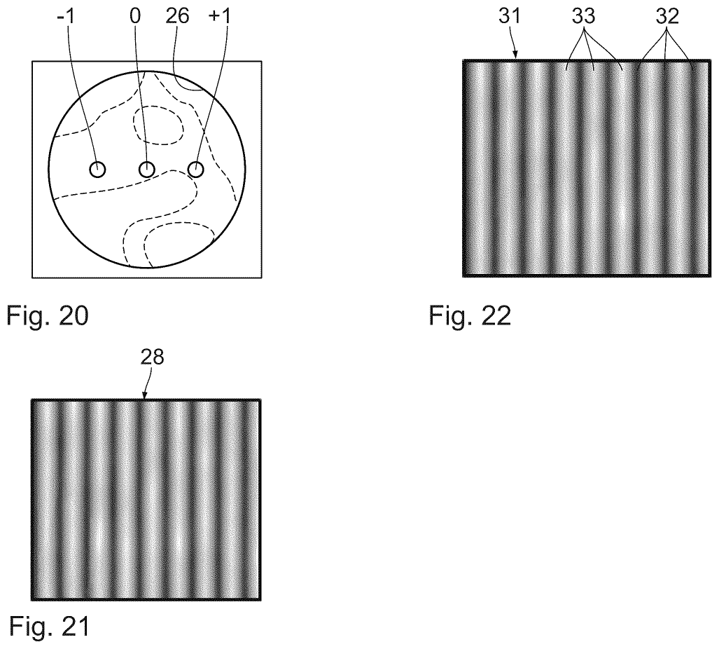

FIG. 19 shows the entrance pupil 24 and the three orders of diffraction of the diffraction spectrum 21 which are located within the entrance pupil 24 in the initial illumination angle distribution, specifically the 0th and the +/−1st orders of diffraction.

FIG. 20 shows a distribution of an intensity of the illumination/imaging light 1 in an exit pupil plane of the projection optical unit 20. An exit pupil 26 depicted in FIG. 21 arises as an image of the entrance pupil 24.

The pupils 24 (cf. FIG. 19) and 26 (cf. FIG. 20) are elliptical. The pupils 22, 24 may also have different deviations from the circular form in the case of alternative specifications by way of appropriate aperture stops 21, with the pupils possibly being at least approximately circular. A pupil radius can be calculated as a mean radius. For instance, such alternative pupils can have an elliptical embodiment with an aspect ratio between the semi-axes ranging between 1 and e.g. 3. The pupils 24 and 26 may also be circular in an embodiment not depicted here.

Firstly, the images of the −1st, 0th and +1st orders of diffraction and, secondly, an imaging contribution of the optical system, specifically the projection optical unit 20, contribute to the intensity distribution in the exit pupil 26. This imaging contribution which is elucidated in FIG. 20 by dashed height contours can be described by an optical system transfer function, as is yet to be explained below. Unavoidable imaging aberrations of the optical system lead to a measurable intensity of the illumination/imaging light 1 being present in the exit pupil 26, even in regions around the orders of diffraction.

The projection optical unit 20 images the test structure 5 towards a spatially resolving detection device 27 of the metrology system 2. The detection device 27 is in the form of a camera, in particular a CCD camera or CMOS camera.

The projection optical unit 20 is embodied as magnifying optical unit. A magnification factor of the projection optical unit 20 may be greater than 10, may be greater than 50, may be greater than 100 and may even be greater still. As a rule, this magnification factor is less than 1000.

In a manner corresponding to FIG. 18, FIG. 21 shows a complex field distribution 28 of the illumination/imaging light 1 in the region of an image plane 29 in which the detection device 27 is arranged.

FIG. 22 shows an illumination/imaging light 1 intensity distribution 31, as measured in an image field 30 in the image plane 29 by the camera 27. Images of the absorber lines 6 are present in the intensity distribution 31 as substantially dark lines 32 of low intensity and images of the multilayer lines 7 are present as bright lines 33 of greater intensity in the intensity distribution 31.

The following procedure is carried out to simulate the illumination and imaging properties of the optical production system when illuminating and imaging the object, using the example of the test structure 5, by use of the optical measurement system 1 of the metrology system 2:

Initially, a plurality of pupil stops 10 with in each case different stop boundary shapes are provided for the purposes of specifying correspondingly different measurement illumination settings. This is implemented by providing pupil stops 10, for example in the style of the pupil stops 10 of FIGS. 2A to 9D, in a stop storage unit accessible to the stop interchange unit, which may be part of the displacement drive 16.

Then, a target pupil stop with a target stop boundary shape is specified proceeding from an illumination setting of the optical production system to be simulated. The target pupil stop can be an arrangement of a plurality or multiplicity of individual pupil spots or stop spots. In this case, the intensity of individual illumination spots or pupil spots generally differs between the individual spots.

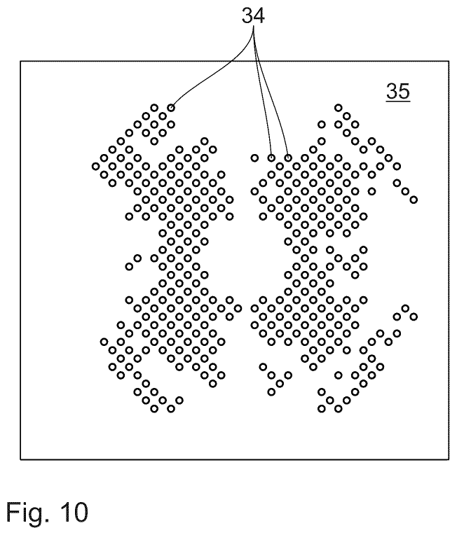

FIG. 10 shows a first example of an illumination setting of the optical production system to be simulated. This production illumination setting in a pupil plane of an optical production system illumination optical unit is provided by way of a fly's eye integrator with a field facet mirror and a pupil facet mirror and comprises a plurality of intensity spots 34, arranged in grid-like fashion, in a production illumination optical unit illumination pupil plane 35. The intensity spots 34 may have different intensities, and so the illumination light from different illumination directions may be incident on the object field 3 with correspondingly different intensities.

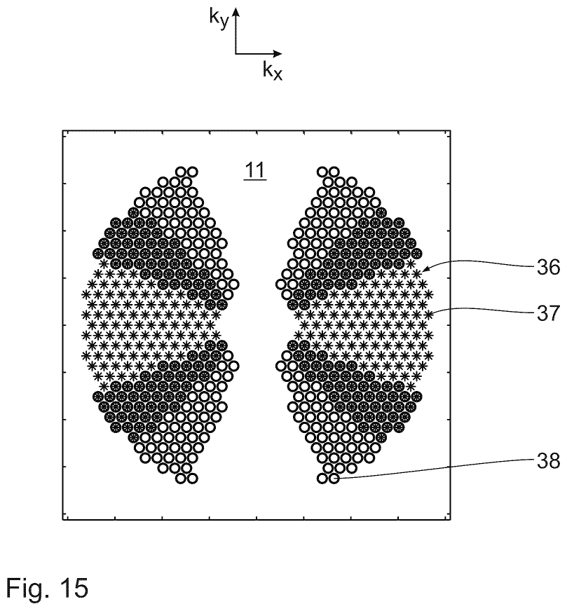

FIG. 15 likewise shows a target pupil stop 36 in a pupil plane with pupil coordinates kₓ, k_{y}, the target stop boundary shape of said target pupil stop being specified in a manner dependent on the illumination setting of the optical production system to be simulated, for example dependent on the illumination setting according to FIG. 10.

The target pupil stop 36 can be specified by way of a definition of appropriate stop aperture contours, especially continuous stop aperture contours. Such stop aperture contours can be described by polygonal chains, for example.

These continuous openings are then approximated by a finite number of pupil spots 37 within the openings. These spots are depicted in FIG. 15 by way of example.

For the specific example in FIG. 15, the aperture contour of the stop in FIG. 7A was used as measurement stop and the aperture contour of the stop in FIG. 5A was used as target setting.

The finer the grid of illumination spots, the more accurately the actual stop shape can be approximated.

FIG. 15 depicts a grid of pupil spots 37 (stars in FIG. 15) which are arranged within the specified target pupil stop 36. This grid arrangement of the pupil spots 37 can take account of shadowing, in particular as a result of required webs of the pupil stop.

Proceeding from this target pupil stop 36, at least one pupil stop 10 is then selected from the provided plurality of pupil stops 10 by use of an algorithm which qualifies deviations between the respective stop boundary shape of the provided pupil stops 10 and the target stop boundary shape of the target pupil stop 36. To this end, the pupil stop 10 currently under examination during the selection (also referred to as pupil stop to be qualified below) can in turn be decomposed within its stop boundary into a plurality of pupil spots 38 arranged in grid-like fashion and represented by circles in FIG. 15.

The scope of qualification comprises determining the similarity between the target illumination pupil (also denoted “T” below) and the possible measurement stops 10 (also denoted “M” below). For instance, this can be implemented by calculating an overlap function Q.

$$Q = \frac{A ( M ⋂ T )}{A ( M ⋃ T )} - \frac{A ( M \backslash T )}{A ( M )} - \frac{A ( T \backslash M )}{A ( T )}$$

Here, A is a function for (approximately) calculating the area. The first term corresponds to the normalized area of the overlap between measurement stop and target illumination pupil. The second and third terms correspond to the normalized difference area between the measurement stop and the target illumination pupil, and vice versa. The difference area is intended to refer to the area contained only in the first pupil and not in the second.

The operators “∩”, “∪” and “\” correspond to the intersection (∩), union (∪) and relative complement (\) operators from set theory. In this case, the intersection M₁∩M₂ of the sets/areas M₁ and M₂ is intended to mean the set/area which is contained both in M₁ and in M₂, i.e. corresponds to the overlap area of M₁ and M₂. The union M₁∪ M₂ of the sets/areas M₁ and M₂ describes the set/area which is contained in M₁ or M₂, i.e. corresponds to the overall area covered by M₁ or M₂. The relative complement M₁\M₂ of the sets/areas M₁ and M₂ describes the set/area which is covered by M₁ but not contained in M₂.

For instance, the area function A can be implemented as counting illumination spots in the pupil. To this end, the target illumination pupil and measurement pupil are equipped with the same grid. Typically, the grid corresponds to the pupil facet grid in the scanner on which the target illumination pupil is sampled (cf. FIG. 10). Now, the number of spots present in both illumination pupils (first term in the formula above) are counted, as are the spots that are exclusive to only one of the two pupils (second and third term in the formula above). In an alternative to that, comparison of the local spot density or the mean local brightness is also conceivable.

Thus, the selection of the pupil stop 10 encompasses a comparison between the poses of pupil spots 37 of the target stop boundary shape and the poses of pupil spots 38 of the provided pupil stops 10.

Moreover, a plurality of defocus values zₘ (cf. FIG. 1) are specified as z-distances of a position of the object holder 17 from the object plane 4 (parallel to the xy-plane).

Moreover, a plurality of measurement positions (kₓ, k_{y}) of the selected pupil stop 10 are specified within the scope of the simulation method.

Now, measurement aerial images I(x, y) in the style of the intensity distributions 31 according to FIG. 22 are recorded in the image plane 29 for a plurality of combinations of in each case a specified defocus value zₘ and a measurement position (kₓ, k_{y}) of the selected pupil stop 10. This is carried out for all positions of the object holder 17 which are assigned to the previously specified defocus values zₘ. For at least one of the specified defocus values zₘ, a plurality of measurement positions (kₓ, k_{y}) of the selected pupil stop 10 are homed in on by way of the displacement drive 16 in order to make the respective recording of the measurement aerial image I(x,y).

The sequence in FIGS. 11A to 11I shows such a combination of one defocus value zₘ and a total of nine measurement positions (kₓ, k_{y}) of the pupil stop 10, with the pupil stop 10 according to FIG. 2B having been chosen here for the purpose of specifying a conventional illumination setting. Depicted in each case is the position of passage pole I of the pupil stop 10 relative to the position of the imaging pupil stop 23.

FIG. 11A shows the pupil stop 10 centered with respect to the imaging pupil stop 23. In this starting position according to FIG. 11A, the pupil stop 10 is imaged centered in the aperture of the imaging pupil stop 23.

In comparison with the imaging pupil stop 23, FIG. 11B shows the pupil stop 10 displaced from the center position according to FIG. 11A by a specified increment in the positive kₓ-direction.

In comparison with the centered position according to FIG. 11A, the following sequence in FIGS. 11C to 11I in each case shows a further displacement of the pupil stop 10 through 45° in the circumferential direction, starting from the position according to FIG. 11B. Hence, the measurement positions according to FIGS. 11C, 11E, 11G and 11I show the pupil stop 10 in the positions of the four quadrants I to IV. The measurement positions according to FIGS. 11B, 11D, 11F and 11H show the pupil stop 10 in the Cartesian displacement positions +kₓ, +k_{y}, −kₓ, −k_{y}.

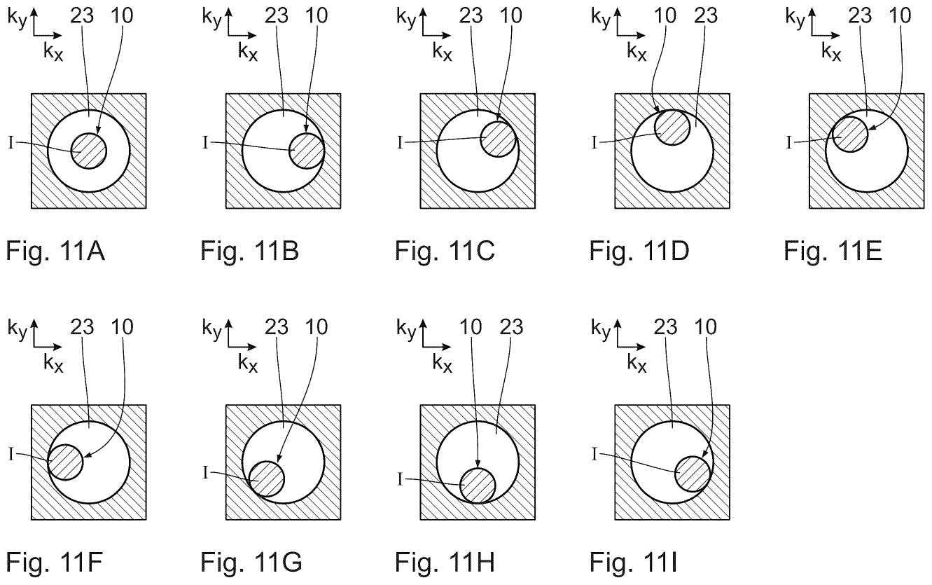

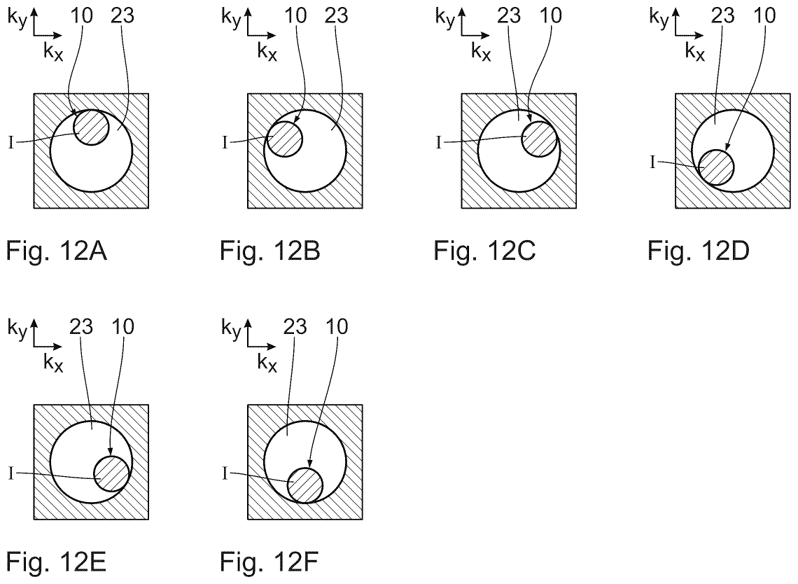

An alternative sequence of measurement positions (kₓ, k_{y}) of the pupil stop 10 is depicted in FIGS. 12A to 12F. This sequence of the measurement positions 12A to 12F corresponds to the measurement positions according to FIGS. 11D, 11E, 11C, 11G, 11I and 11H.

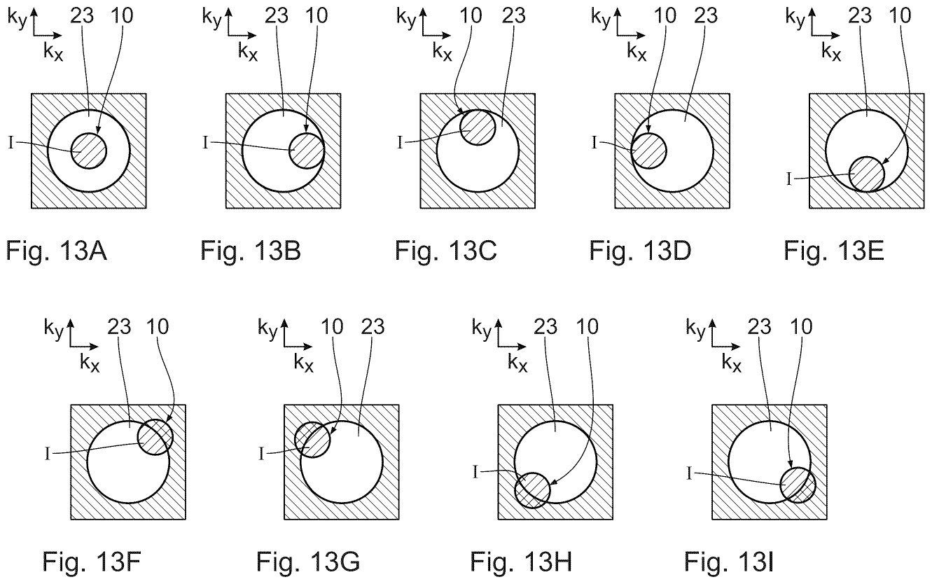

FIGS. 13A to 13I show a further variant of a sequence of measurement positions (kₓ, k_{y}) of the pupil stop 10.

FIG. 13A shows the pupil stop 10 once again centered with respect to the imaging pupil stop 23. In comparison with the imaging pupil stop 23, FIG. 13B shows the pupil stop 10 displaced from the center position according to FIG. 13A by a specified increment in the positive kₓ-direction.

Relative to the imaging pupil stop 23, FIG. 13C shows the pupil stop 10 displaced in the positive k_{y}-direction from the center position according to FIG. 13 by the same increment.

Relative to the imaging pupil stop 23, FIG. 13D shows the pupil stop 10 displaced by the increment in the negative kₓ-direction starting from the center position according to FIG. 13A.

Relative to the imaging pupil stop 23, FIG. 13E shows the pupil stop 10 displaced by the given increment in the negative k_{y}-direction starting from the center position according to FIG. 13A.

The completed sequence of measurement positions (kₓ, k_{y}) is shown in FIGS. 13F to 13I. The circumferential positions of the pupil stop 10 relative to the imaging pupil stop 23 correspond there to the positions according to FIGS. 11C, 11E, 11G and 11I. In contrast to these positions, the pupil stop 10 in the sequence according to FIGS. 13F to 13I has been pushed so far out of the aperture of the imaging pupil stop 23 in the radial direction that only an inner part of the passage spot I of the pupil stop 10 still overlaps with the aperture of the imaging pupil stop 23. Just slightly over half of the area of the passage spot I can be traversed by the illumination light in this case. This yields a complete sequence according to FIGS. 13A to 13I with two displacement radii.

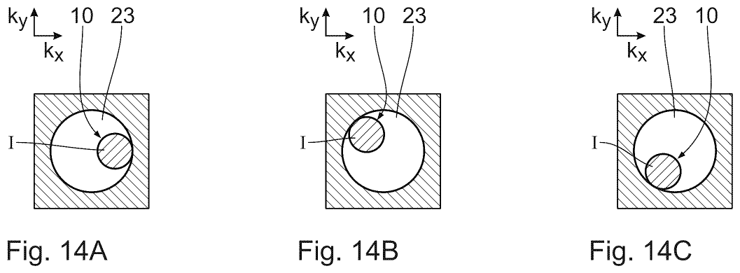

FIGS. 14A to 14C show a further variant of a sequence of measurement positions (kₓ, k_{y}) of the pupil stop 10. The measurement positions according to FIGS. 14A to 14C correspond to the measurement positions according to FIGS. 11B, 11E and 11G.

The selection of the respective measurement position sequence, or optionally a subset therefrom, is implemented on the basis of the arrangement of individual structures of the test structure 5 and/or on the basis of the illumination setting of the optical production system to be simulated. For instance, the measurement position sequence can be selected in a manner analogous to the stop selection algorithm (see above), with all stop positions of a sequence being taken into account and the sequence being selected for which the overlap of the measurement sequence with the target illumination pupil is maximal.

The poses of the pupil stop 10 which differ from the center position in terms of the relative pose with respect to the imaging pupil stop 23 are also referred to as offset measurement positions. Within the scope of a measurement position sequence, two to ten such offset measurement positions can be homed in on, this typically being two to five offset measurement positions, for example three or four offset measurement positions. The offset measurement positions can be arranged uniformly distributed in the circumferential direction. To reduce the measurement time, it is also possible to use only a subset, e.g. every second measurement position, from the measurement schemes (FIG. 11 to FIG. 14) shown.

The specified defocus values zₘ are all measured with the aid of the respective measurement position sequence. In an alternative, it is possible that the entire respective measurement position sequence is used only for one defocus value or for individual defocus values zₘ, with the measurement aerial images being recorded for fewer measurement positions of the pupil stop relative to the imaging pupil stop 23 in the case of other defocus values zₘ. In an extreme case, it is possible for example to home in on the full measurement position sequence and record a respective measurement aerial image there for only one defocus value zₘ, whereas the measurement aerial image Iₘₑₐₛ(x, y) is only recorded at one respective measurement position, in particular for the case of the centered pupil stop 10, in the case of the other specified defocus values zₘ.

For instance, the following defocus value/measurement position combinations can be recorded: A central defocus value zₘ and a plurality of measurement positions (kₓ, k_{y}) of the pupil stop 10, i.e., in particular, a centered measurement position and a plurality of offset measurement positions, and defocus values zₘᵢₙ, zₘₐₓ maximally offset from the central defocus value on both sides, with exactly one central measurement position (kₓ, k_{y}) of the pupil stop 10 being adopted at these positions zₘᵢₙ, zₘₐₓ.

Then, a complex mask transfer function is reconstructed from the totality of measurement aerial images recorded with the selected pupil stop 10. A similar reconstruction step is also described in DE 10 2019 215 800 A1.

The reconstruction is implemented within the scope of a modelled description, within which the projection optical unit 20 of the metrology system 2 with the illumination setting specified by the pupil stop 10 is described by a function σ(\vec{p}) which reproduces the illumination directions \vec{p} which are passed through the pupil stop 10. A displacement of the pupil stop 10 by a vector \vec{q} with absolute coordinate values kₓ and k_{y} leads to a displaced illumination function σ(\vec{p}−\vec{q}).

Each illumination direction generates a complex-valued field distribution m(\vec{r},\vec{p}) (cf. the field distribution 19 in FIG. 17) in the object plane (4) as a result of an interaction with the test structure 5. This distribution depending on not only the field point \vec{r} but also the illumination direction \vec{p} is explicitly taken into account here. The field distribution interferes in the entrance pupil 24 of the imaging optical unit 20 to form a likewise complex-valued diffraction spectrum M(\vec{k},\vec{p}) (cf. diffraction spectrum 21 in FIG. 19) corresponding to the Fourier transform of the field distribution m of the test structure 5. The propagation through the projection optical unit 20 of the metrology system 2 can be modelled by multiplication with the known, complex-valued transfer function P of the projection optical unit 20:

$$P ( \vec{k} , z ) = NA ( \vec{k} ) {e}^{i \frac{2 π}{λ}} z \sqrt{1 - {\vert k \vert}^{2}} \\ Here , NA ( \vec{k} ) = \begin{matrix}1 for \vert k \vert \leq NA \\ 0 for \vert k \vert > NA\end{matrix} \qquad ( 1 )$$

is the curtailment by the numerical aperture of the imaging optical unit 20, that is to say by the imaging pupil stop 23, and

$${e}^{i \frac{2 π}{λ}} z \sqrt{1 - {\vert k \vert}^{2}}$$

is a wavefront error caused by a defocus z (displacement by the object holder 17). The propagated spectrum (cf. FIG. 21) now interferes to form the field distribution 28 in the image plane 29. The camera measures the intensity 31 of the field distribution 28 integrated over all illumination directions of the illumination system. Thus, the aerial image measured with the defocus z and the illumination direction q can be described as follows and can be simulated by inserting a candidate for the mask spectrum M:

$${I}_{sim} ( \vec{r} , z , \vec{q} ) = \int d \vec{p} σ ( \vec{p} - \vec{q} ) {\vert \int d \vec{k} M ( \vec{k} , \vec{p} ) P ( \vec{k} , z ) {e}^{i \vec{k} \vec{r}} \vert}^{2} \qquad ( 2 )$$

In this case, \vec{r} is the xy-position of the intensity measurement, i.e. the respective pixel of the camera 27.

The object now is to determine the mask spectrum M(\vec{k},\vec{p}). In this case, k is the pupil coordinates in the entrance pupil 24 of the projection optical unit 20 and \vec{p} is the illumination direction. The Fourier transform of the respective mask spectrum is the associated mask transfer function.

The reconstructed spectra can then be used to calculate the aerial image for any other illumination setting σ_{target}(\vec{p})) and any defocus z_{target}.

The determination of M(\vec{k},\vec{p}) can be formulated as an optimization problem: Sought are the spectra M(\vec{k},\vec{p}) for which there is a minimum deviation F between the simulated aerial images and the aerial images Iₘₑₐₛ measured at the defocus positions z₁, z₂ . . . z_{N} and the illumination directions \vec{q}₁, \vec{q}₂ . . . \vec{q}_{M}. The following optimization problem should be solved:

$${min}_{M ( \vec{k} , \vec{p} )} F = {min}_{M ( \vec{k} , \vec{p} )} {\sum }_{n} {\sum }_{m} \int d \vec{r} {\vert {I}_{sim} ( \vec{r} , {z}_{n} , {\vec{q}}_{m} ) - {I}_{meas} ( \vec{r} , {z}_{n} , {\vec{q}}_{m} ) \vert}^{2} \qquad ( 3 )$$

A separate spectrum needs to be reconstructed for each illumination direction 5. As a rule, the optimization problem is underdetermined. There are various options for handling this problem.

The simplest solution is a Hopkins approximation, which assumes that the spectrum is only displaced by the same value in the case of a displacement of the illumination direction, that is to say M(\vec{k},\vec{p})=M₀(\vec{k}−\vec{p}). As a result, there now is only still one spectrum that it needs to be reconstructed. The angle dependence of the reflectivity, shadowing effects and mask-induced aberrations means that the dependence of the mask spectrum on the illumination direction is not completely negligible in the case of real EUV lithography masks as test structures 5. The Hopkins approximation is stretched to its limits.

To take account of the dependence of the spectrum and the illumination direction 5, the following ansatz can be considered for the angle-dependent spectrum M of the test structure 5:

$$M ( \vec{k} , \vec{p} ) = {M}_{0} ( \vec{k} - \vec{p} ) \cdot C ( \vec{k} , \vec{p} , {α}_{1} , {α}_{2} , … , {α}_{N} ) \qquad ( 4 )$$

In this case, M₀(\vec{k}) is a spectrum that is independent of the illumination direction, in a manner analogous to the Hopkins approximation. C(\vec{k},\vec{p},\vec{α}) is any complex-valued function albeit defined prior to the reconstruction, which models the dependence of the amplitude and phase on the illumination direction. α_{1 . . . N} are free parameters, which are determined within the scope of the optimization.

By way of example, the following the function C(\vec{k}, \vec{p}, α₁, α₂, . . . , α_{N}) could be used:

$$C ( \vec{k} , \vec{p} , {α}_{1} , {α}_{2} ) = ( {α}_{1} \cdot {\vert \vec{k} + \vec{p} \vert}^{2} + i {α}_{2} \cdot {\vert \vec{k} + \vec{p} \vert}^{4} )$$

Within the scope of reconstructing the complex mask transfer function M, a mask spectrum M(\vec{p}) that is dependent on the illumination direction is modelled as a product of a spectrum that is independent of the illumination direction and a correction function (C(\vec{k}, \vec{p}, \vec{α}₁, \vec{α}₂, . . . , α_{N})).

Now, the mask spectrum M₀(\vec{k}) and the parameters α_{1 . . . N} which minimize the difference between measured and simulated aerial images are sought after. The following optimization problem is solved:

$${min}_{{M}_{0} , α} F = {min}_{{M}_{0} , α} {\sum }_{n} {\sum }_{m} \int d \vec{r} {\vert {I}_{sim} ( \vec{r} , {z}_{n} , {\vec{q}}_{m} ) - {I}_{meas} ( \vec{r} , {z}_{n} , {\vec{q}}_{m} ) \vert}^{2} \qquad ( 5 )$$

Thus, the number of free parameters is only increased by N vis-a-vis the Hopkins approximation, with N typically being small.

Using the reconstructed, now directionally dependent spectrum, it is possible to calculate a simulated aerial image Iₛᵢₘ for the target illumination setting G_{target} and the target defocus z_{target}:

$${I}_{sim} ( \vec{r} , z ) = \int d \vec{p} {σ}_{target} ( \vec{p} ) {\vert \int d \vec{k} M ( \vec{k} , \vec{p} ) P ( \vec{k} , {z}_{target} ) {e}^{i \vec{k} \vec{r}} \vert}^{2} \qquad ( 6 )$$

Equation (6) then allows comparison between the simulated aerial image Iₛᵢₘ and the respectively measured aerial image Iₘₑₐₛ, and this can be used to reconstruct the mask spectrum M and, accordingly, the complex mask transfer function.

From Equation (6), the 3-D aerial image can be calculated with the aid of the reconstructed mask transfer function M and the illumination setting G_{target} of the optical production system. In this way, it is possible to ascertain what the aerial image of the test structure 5 would look like if it were imaged by the optical production system.

In a variant of the simulation method, it is also possible to use a plurality of different pupil stops 10 to specify the various measurement positions (kₓ, k_{y}).

To prepare the simulation method, it is possible to record an aerial image stack in order to make sure which z-pose of the object plane 4 supplies an optimally sharp image in the image plane 29 (zero of the z-pose).

z-increments which are used in Equation (6) when determining the aerial image Iₛᵢₘ may differ from the defocus values zₘ that are specified within the scope of the simulation method.

Pixel sizes of the recorded measurement aerial images Iₘₑₐₛ may be re-sampled for the purpose of matching to a desired pixel resolution.

A plurality of kₓ, k_{y} positions of the imaging pupil stop 23 can also be set by way of the displacement drive 25 in a simulation method.

When reconstructing the mask transfer function, it is accordingly possible to take account of imaging aberrations of the optical measurement system, in particular imaging aberrations of the imaging optical unit 20 of the metrology system 2.

The determination of the 3-D aerial image Iₘₑₐₛ and/or the calculation of the simulated aerial image Iₛᵢₘ may be carried out using a different illumination chief ray angle to that of the reconstruction of the mask transfer function.

For selecting the respective pupil stop 10 from the provided plurality of pupil stops 10 with in each case different stop boundary shapes and/or stop boundary orientations, the metrology system 2 has a selection apparatus not depicted in detail in the drawing. This selection apparatus has a stop storage unit, in which the plurality of pupil stops 10 with in each case different stop boundary shapes and/or stop boundary orientations are stored for the purpose of specifying correspondingly different measurement illumination settings.

In the selection step of the simulation method, the last pupil stop inserted is firstly removed from its use location in the pupil plane 11 and supplied to the stop storage unit in the selection apparatus with the aid of an actuator system of the selection apparatus, in particular with the aid of a robotic actuator system. Subsequently, the pupil stop 10 selected according to the simulation method is selected from the stop storage unit and inserted in the use position in the pupil plane 11 with the aid of the robotic actuator system.

What is claimed is:

1. A method for simulating illumination and imaging properties of an optical production system during the illumination and imaging of an object by use of an optical measurement system of a metrology system,
the optical measurement system comprising an illumination optical unit for illuminating the object having a pupil stop in the region of an illumination pupil in a kₓ, k_{y} pupil plane, and an imaging optical unit for imaging the object into an image plane,
comprising the following steps:
providing a plurality of pupil stops for specifying different measurement illumination settings,
recording measurement aerial images Iₘₑₐₛ (x, y) in the image plane by use of the plurality of pupil stops,
reconstructing a complex mask transfer function from the recorded measurement aerial images (Iₘₑₐₛ), and
determining a 3-D aerial image of the optical production system from the reconstructed mask transfer function and an illumination setting of the optical production system as the result of the simulation method.

2. The method of claim 1, wherein the optical measurement system comprises a displacement drive for displacing the pupil stop in the kₓ- and/or k_{y}-direction, the optical measurement system comprising an object holder that is displaceable perpendicular to an xy-object plane by actuator.

3. The method of claim 1, wherein the plurality of pupil stops have in each case different stop boundary shapes and/or stop boundary orientations for specifying correspondingly different measurement illumination settings.

4. The method of claim 1, wherein the method furthermore includes the following steps:
specifying a target pupil stop with a target stop boundary shape proceeding from an illumination setting of the optical production system,
selecting at least one pupil stop from the plurality of pupil stops by use of an algorithm which qualifies deviations between the respective stop boundary shape of the pupil stops and the target stop boundary shape,
specifying a plurality of defocus values zₘ as z-distances of an object holder position from the xy-object plane, and
specifying a plurality of measurement positions (kₓ, k_{y}) of the at least one selected pupil stop.

5. The method of claim 4, wherein the measurement aerial images Iₘₑₐₛ (x, y) are recorded for a plurality of combinations of in each case a specified defocus value (zₘ) and a specified measurement position (kₓ, k_{y}) of the pupil stop, at all object holder positions assigned to the specified defocus values zₘ, with a plurality of the specified measurement positions (kₓ, k_{y}) being homed in on for at least one of the specified defocus values zₘ, for the respective recording of a measurement aerial image (Iₘₑₐₛ).

6. The method of claim 4, wherein the specified measurement positions (kₓ, k_{y}) of the pupil stop include a central measurement position and a plurality of offset measurement positions surrounding said central measurement position.

7. The method of claim 4, wherein the measurement aerial images (Iₘₑₐₛ) are recorded for at least the following defocus value/measurement position combinations:
a central defocus value (zₘ) and a plurality of measurement positions (kₓ, k_{y}) of the pupil stop,
defocus values (zₘᵢₙ, zₘₐₓ) maximally offset from the central defocus value (zₘ) on both sides of the central defocus value (zₘ) perpendicular to the xy-object plane, and exactly one measurement position (kₓ, k_{y}) of the pupil stop at each location there.

8. The method of claim 4, wherein a comparison of locations of pupil spots of the target stop boundary shape with locations of pupil spots of the provided pupil stops is implemented when selecting the pupil stop.

9. The method of claim 1, wherein a mask spectrum dependent on the illumination direction is modelled during the reconstruction of the complex mask transfer function as a product of an illumination direction-independent mask spectrum and an illumination direction-dependent correction function.

10. The method of claim 1, wherein the optical measurement system comprises an imaging pupil stop in the region of a pupil of the imaging optical unit, with a plurality of measurement positions of the imaging pupil stop being specified, a plurality of specified measurement positions of the imaging pupil stop being set when recording the measurement aerial images (Iₘₑₐₛ).

11. The method of claim 1, wherein imaging aberrations of the optical measurement system are taken into account when reconstructing the mask transfer function.

12. The method of claim 1, wherein the 3-D aerial image is determined using a different illumination chief ray angle to the one used in the reconstruction of the mask transfer function.

13. A metrology system for carrying out a method as claimed in claim 1,
the optical measurement system comprising an illumination optical unit for illuminating the object having a pupil stop in the region of an illumination pupil in a kₓ, k_{y} pupil plane, and an imaging optical unit for imaging the object in the image plane.

14. The metrology system of claim 13,
the optical measurement system comprising a displacement drive for displacing the pupil stop in the kₓ- and/or in the k_{y}-direction,
the optical measurement system comprising an object holder that is displaceable perpendicular to a xy-object plane by actuator.

15. The metrology system of claim 13, wherein the optical measurement system comprises a displacement drive for displacing, in the kₓ- and/or k_{y}-direction, an imaging pupil stop arranged in the region of a pupil of the imaging optical unit.

16. The metrology system of claim 13, comprising a selection apparatus for selecting at least one pupil stop from a plurality of pupil stops, wherein the selection apparatus comprises a stop storage unit with a plurality of pupil stops, with in each case different stop boundary shapes and/or stop boundary orientations for specifying correspondingly different measurement illumination settings.

17. The metrology system of claim 14, wherein the optical measurement system comprises a displacement drive for displacing, in the kₓ- and/or k_{y}-direction, an imaging pupil stop arranged in the region of a pupil of the imaging optical unit.

18. The metrology system of claim 14, comprising a selection apparatus for selecting at least one pupil stop from a plurality of pupil stops, wherein the selection apparatus comprises a stop storage unit with a plurality of pupil stops, with in each case different stop boundary shapes and/or stop boundary orientations for specifying correspondingly different measurement illumination settings.

19. The method of claim 2, wherein the plurality of pupil stops have in each case different stop boundary shapes and/or stop boundary orientations for specifying correspondingly different measurement illumination settings.

20. The method of claim 2, wherein the method furthermore includes the following steps:
specifying a target pupil stop with a target stop boundary shape proceeding from an illumination setting of the optical production system,
selecting at least one pupil stop from the plurality of pupil stops by use of an algorithm which qualifies deviations between the respective stop boundary shape of the pupil stops and the target stop boundary shape,
specifying a plurality of defocus values zₘ as z-distances of an object holder position from the xy-object plane, and
specifying a plurality of measurement positions (kₓ, k_{y}) of the at least one selected pupil stop.
